(19) United States
(12) Patent Application Publication
(10) Pub. No.: US 2003/0003374 A1
(43) Pub. Date: Jan. 2, 2003

(54) Etch process for photolithographic reticle manufacturing with improved etch bias

(75) Inventors: Melisa Buie, San Jose, CA (US); Brigitte Stoehr, San Jose, CA (US); Guenther Ruhl, Dorfen (DE)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/024,958

(22) Filed: Dec. 18, 2001

Related U.S. Application Data
(63) Continuation-in-part of application No. PCT/US01/19282, filed on Jun. 15, 2001.

(30) Foreign Application Priority Data
Sep. 24, 2001 (DE) 101 46 935.7

(51) Int. Cl. G03F 9/00; C23F 1/00; B44C 1/22; C03C 15/00; C03C 25/68; H01L 21/302; H01L 21/461

(52) U.S. Cl. 430/5; 216/67; 216/63; 438/723

(57) ABSTRACT

Method and apparatus for etching a metal layer disposed on a substrate, such as a photolithographic reticle, are provided. In one aspect, a method is provided for processing a substrate including positioning a substrate having a metal photomask layer disposed on a silicon-based material in a processing chamber, introducing a processing gas comprising carbon monoxide, a chlorine containing gas, and optionally, an inert gas into the processing chamber, generating a plasma of the processing gas in the processing chamber, and etching exposed portions of the metal layer disposed on the substrate.

### CROSS-REFERENCE TO RELATED APPLICATIONS

This application is a continuation-in-part of co-pending PCT Patent Application No. PCT/US01/19282, filed on Jun. 15, 2001, designating the United States, which is incorporated herein by reference.

### BACKGROUND OF THE INVENTION

1. Field of the Invention

The present invention relates to the fabrication of integrated circuits and to the fabrication of photolithographic reticles useful in the manufacture of integrated circuits.

2. Background of the Related Art

Semiconductor device geometries have dramatically decreased in size since such devices were first introduced several decades ago. Since then, integrated circuits have generally followed the two year/half-size rule (often called Moore's Law), which means that the number of devices on a chip doubles every two years. Today's fabrication plants are routinely producing devices having 0.15 μm and even 0.13 μm feature sizes, and tomorrow's plants soon will be producing devices having even smaller geometries.

The increasing circuit densities have placed additional demands on processes used to fabricate semi-conductor devices. For example, as circuit densities increase, the widths of vias, contacts and other features, as well as the dielectric materials between them, decrease to sub-micron dimensions, whereas the thickness of the dielectric layers remains substantially constant, with the result that the aspect ratios for the features, i.e., their height divided by width, increases. Reliable formation of high aspect ratio features is important to the success of sub-micron technology and to the continued effort to increase circuit density and quality of individual substrates.

High aspect ratio features are conventionally formed by patterning a surface of a substrate to define the dimensions of the features and then etching the substrate to remove material and define the features. To form high aspect ratio features with a desired ratio of height to width, the dimensions of the features are required to be formed within certain parameters, which are typically defined as the critical dimensions of the features. Consequently, reliable formation of high aspect ratio features with desired critical dimensions requires precise patterning and subsequent etching of the substrate.

Photolithography is a technique used to form precise patterns on the substrate surface and then the patterned substrate surface is etched to form the desired device or features. Photolithography techniques use light patterns and resist materials deposited on a substrate surface to develop precise patterns on the substrate surface prior to the etching process. In conventional photolithographic processes, a resist is applied on the layer to be etched, and the features to be etched in the layer, such as contacts, vias, or interconnects, are defined by exposing the resist to a pattern of light through a photolithographic reticle having a photomask layer disposed thereon, which corresponds to the desired configuration of features. A light source emitting ultraviolet (UV) light, for example, may be used to expose the resist to alter the composition of the resist. Generally, the exposed resist material is removed by a chemical process to expose the underlying substrate material. The exposed underlying substrate material is then etched to form the features in the substrate surface while the retained resist material remains as a protective coating for the unexposed underlying substrate material.

Photolithographic reticles typically include a substrate made of an optically transparent silicon based material, such as quartz (i.e., silicon dioxide, SiO₂), having an opaque light-shielding layer of metal or photomask, typically chromium, disposed on the surface of the substrate. The metal layer is patterned to correspond to the features to be transferred to the substrate. Generally, conventional photolithographic reticles are fabricated by first depositing a thin layer of metal on a substrate comprising an optically transparent silicon based material, such as quartz, and depositing a resist layer on the thin metal layer. The resist is then patterned using conventional laser or electron beam patterning equipment to define the critical dimensions to be transferred to the metal layer. The metal layer is then etched to remove the metal material not protected by the patterned resist; thereby exposing the underlying silicon based material and forming a patterned photomask layer. Photomasks layers allow light to pass therethrough in a precise pattern onto the substrate surface.

Conventional etching processes, such as wet etching, tend to etch isotropically, which can result in an undercut phenomenon to occur in the metal layer below the patterned resist. The undercut phenomenon can produce patterned features on the photomask that are not uniformly spaced nor do the features have desired straight, vertical sidewalls, thereby losing the critical dimensions of the features. Additionally, the isotropic etching of the features may overetch the sidewalls of features in high aspect ratios, resulting in the loss of the critical dimensions of the features. Features formed without the desired critical dimensions in the metal layer can detrimentally affect light passing therethrough and result in less than desirable patterning by the photomask in subsequent photolithographic processes.

Plasma etch processing, known as dry etch processing or dry etching, provides an alternative to wet etching and provides a more anisotropic etch than wet etching processes. The dry etching process has been shown to produce less undercutting and improve the retention of the critical dimensions of the photomask features with straighter sidewalls and flatter bottoms. In conventional dry etching processing, a plasma of etching gases, such as chlorine, oxidizing gases, such as oxygen, and inert gases, such as helium, are used to etch the metal layers formed on the substrate.

Oxidizing gases, such as oxygen, promote over-etching or imprecise etching the sidewalls of the openings or pattern formed in the resist material used to define the critical dimensions of the metal layer. Excess side removal of the resist material results in a loss of the critical dimensions of the patterned resist features, which may correspond in a loss of critical dimensions of the features formed in the metal layer defined by the patterned resist layer. Further, imprecise etching may not sufficiently etch the features to provide the necessary critical dimensions. Failure to sufficiently etch the features to the critical dimensions is referred to as a “gain” of critical dimensions. The degree of loss or gain of the critical dimensions in the metal layer is referred to as “etching bias” or “CD bias”. The etching bias can be as large as 120 nm in photomasks patterns used to form 0.14 μm features on substrate surfaces.

The loss or gain of critical dimensions of the pattern formed in the metal layer can detrimentally affect the light passing therethrough and produce numerous patterning and subsequent etching defects in the substrate patterned by the photolithographic reticle. The loss or gain of critical dimensions of the photomask can result in insufficient photolithographic performance for etching high aspect ratios of sub-micron features, and if the loss or gain of critical dimensions is severe enough, the failure of the photolithographic reticle or subsequently etched device.

Therefore, there remains a need for a process and chemistry for etching a metal layer on a substrate, such as a reticle, which produces a pattern with desired critical dimensions in the metal layer.

### SUMMARY OF THE INVENTION

Aspects of the invention generally provide methods and related chemistry for etching a metal layer deposited on a silicon based substrate, such as a photolithographic reticle. In one aspect, a method is provided for processing a photolithographic reticle including positioning the reticle on a support member in a processing chamber, wherein the reticle comprises a metal photomask layer formed on a silicon based substrate and a patterned resist material deposited on the metal photomask layer, introducing a processing gas comprising carbon monoxide and a halogen-containing gas into the processing chamber, wherein the carbon monoxide and the chlorine containing gas have a molar ratio between about 1:9 and about 9:1, and delivering power to the processing chamber to generate a plasma and remove exposed portions of the metal photomask layer.

In another aspect, a method is provided for processing a photolithographic reticle including positioning the reticle on a support member in a processing chamber, wherein the reticle comprises a chromium based photomask layer formed on an optically transparent silicon based material and a patterned resist material deposited on the chromium based photomask layer, introducing a processing gas comprising carbon monoxide and chlorine gas, wherein the molar ratio between carbon monoxide and chlorine gas is about 1:1, introducing an inert gas, maintaining a chamber pressure between about 2 milliTorr and about 25 milliTorr, delivering power to the processing chamber of about 700 watts or less to a coil disposed in the processing chamber to generate a plasma, and etching exposed portions of the chromium based photomask layer and selectively removing the chromium based photomask layer at a removal rate ratio of chromium based photomask layer to resist material of about 3:1 or greater.

In another aspect, a method is provided for processing a photolithographic reticle, including positioning the reticle on a support member in a processing chamber having a coil, wherein the reticle comprises a chromium based photomask layer formed on an optically transparent silicon based material and a patterned resist material deposited on the chromium based photomask layer, introducing a processing gas comprising carbon monoxide, chlorine gas, and an oxygen-containing gas into the processing chamber, wherein the molar ratio between carbon monoxide and chlorine gas is about 1:1, and the oxygen-containing gas comprises between about 5% and about 45% of the processing gas, introducing helium into the processing chamber, generating a plasma in the processing chamber, and etching exposed portions of the chromium based photomask layer and selectively removing the chromium based photomask layer at a removal rate ratio of chromium based photomask layer to resist material of about 3:1 or greater.

### BRIEF DESCRIPTION OF THE DRAWINGS

So that the manner in which the above recited aspects of the invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a schematic side view of one embodiment of an etching chamber;

FIG. 2 is a flow chart illustrating one embodiment of a sequence for processing a substrate according to one embodiment of the invention;

FIGS. 3A-3E are cross sectional views showing an etching sequence of another embodiment of the invention.

### DETAILED DESCRIPTION OF THE EXEMPLARY EMBODIMENT

Aspects of the invention will be described below in reference to an inductively coupled plasma etch chamber, such as a Decoupled Plasma Source, or DPS™, chamber manufactured by Applied Materials, Inc., of Santa Clara, Calif. Other process chambers may be used to perform the processes of the invention, including, for example, capacitively coupled parallel plate chambers and magnetically enhanced ion etch chambers as well as inductively coupled plasma etch chambers of different designs. Although the processes are advantageously performed with the DPS™ processing chamber, the description in conjunction with the DPS™ processing chamber is illustrative, and should not be construed or interpreted to limit the scope of aspects of the invention.

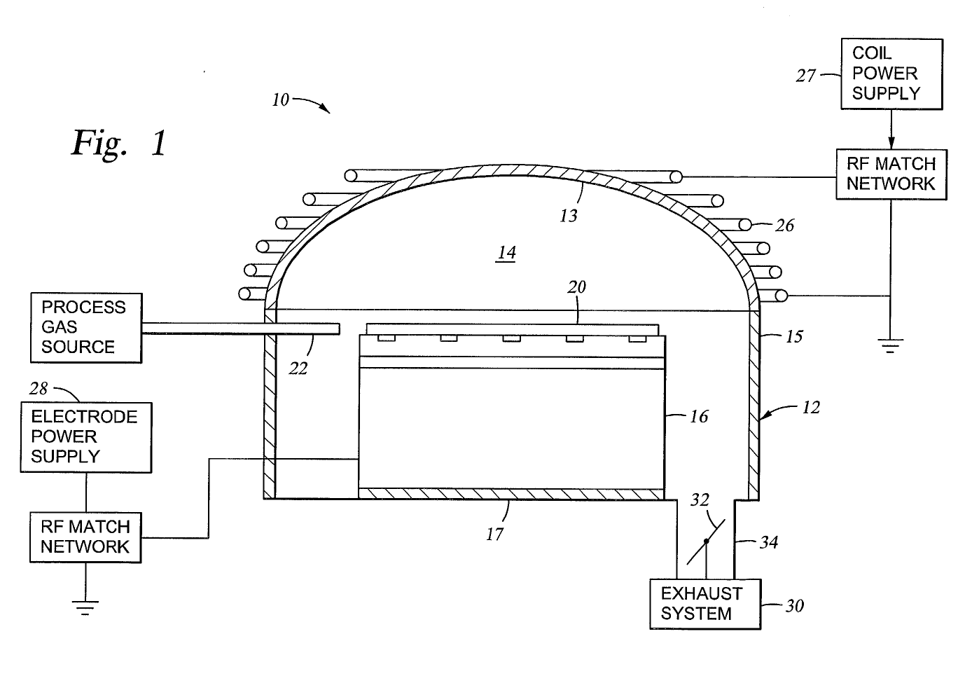

FIG. 1 is a schematic cross sectional view of one embodiment of a DPS™ processing chamber that may be used for performing the processes described herein. The processing chamber 10 generally includes a cylindrical sidewall or chamber body 12, an energy transparent dome ceiling 13 mounted on the body 12, and a chamber bottom 17. An inductive coil 26 is disposed around at least a portion of the dome 13. The chamber body 12 and the chamber bottom 17 of the processing chamber 10 can be made of a metal, such as anodized aluminum, and the dome 13 can be made of an energy transparent material such as a ceramic or other dielectric material.

A substrate support member 16 is disposed in the processing chamber 10 to support a substrate 20 during processing. The support member 16 may be a conventional mechanical or electrostatic chuck with at least a portion of the support member 16 being electrically conductive and capable of serving as a process bias cathode. While not shown, a reticle adapter may be used to secure the reticle on the support member 16. The reticle adapter generally includes a lower portion milled to cover an upper portion of the support member and a top portion having an opening that is sized and shaped to hold a reticle. A suitable reticle adapter is disclosed in U.S. Pat. No. 6,251,217, issued on Jun. 26, 2001, which is incorporated herein by reference to the extent not inconsistent with aspects and claims of the invention.

A plasma zone 14 is defined by the process chamber 10, the substrate support member 16 and the dome 13. Processing gases are introduced into the processing chamber 10 through a gas distributor 22 peripherally disposed about the support member 16. A plasma is formed in the plasma zone 14 from the processing gases using a coil power supply 27 which supplies power to the inductor coil 26 to generate an electromagnetic field in the plasma zone 14. The support member 16 includes an electrode disposed therein, which is powered by an electrode power supply 28 and generates a capacitive electric field in the processing chamber 10. Typically, RF power is applied to the electrode in the support member 16 while the body 12 is electrically grounded. The capacitive electric field is transverse to the plane of the support member 16, and influences the directionality of charged species more normal to the substrate 20 to provide more vertically oriented anisotropic etching of the substrate 20.

Process gases and etchant byproducts are exhausted from the process chamber 10 through an exhaust system 30. The exhaust system 30 may be disposed in the bottom 17 of the processing chamber 10 or may be disposed in the body 12 of the processing chamber 10 for removal of processing gases. A throttle valve 32 is provided in an exhaust port 34 for controlling the pressure in the processing chamber 10. An optical endpoint measurement device can be connected to the processing chamber 10 to determine the endpoint of a process performed in the chamber.

While the following process description illustrates one embodiment of a etching a substrate by the processing gases described herein, the invention contemplates the use of processing parameters outside the ranges described herein for performing this process in different apparatus, such as a different etching chamber, and for different substrate sizes, such as a photolithographic reticles for 300 mm substrate processing.

Exemplary Etch Process

Generally a photolithographic reticle includes a metal layer, such as chromium or chromium oxynitride, known as a photomask, deposited on an optically transparent substrate. The metal layer is etched to produce a photomask layer having features with desired critical dimensions. Carbon monoxide and a chlorine containing gas comprise a processing gas for etching the metal layer. The processing gas may further include an inert gas or another oxygen containing gas. Carbon monoxide is advantageously used to form passivating polymer deposits on the surfaces, particularly the sidewalls, of openings and patterns formed in a patterned resist material and etched metal layers. The passivating polymer deposits prevent excessive etching of the bottom and sidewalls of openings and patterns formed in the resist layers, thereby minimizing etch bias and producing openings and patterns having desired critical dimensions.

Chlorine containing gases are selected from the group of chlorine (Cl₂), silicon tetrachloride (SiCl₄), boron trichloride (BCl₃), and combinations thereof, of which Cl₂ is preferred, are used to supply highly reactive radicals to etch the metal layer. The carbon monoxide and chlorine containing gases are provided in a molar ratio of carbon monoxide to chlorine containing gas of between about 1:9 and about 9:1, i.e., carbon monoxide comprises between about 10% and about 90% of the total moles of the carbon monoxide and chlorine containing gases. A molar ratio of carbon monoxide to chlorine containing gas of about 1:1, i.e., carbon monoxide comprises about 50% of the processing gas, is preferred.

Alternatively, another oxygen containing gas, such as oxygen (O₂), carbon dioxide (CO₂), or combinations thereof, may be added to the processing gas to provide additional etching radicals. Oxygen radicals may remove passivating polymer deposits and minimize the formation of passivating polymer deposits. Thus, the oxygen content of the processing gas may be used to control the amount of passivating deposits being formed. The oxygen containing gas may be added to the processing gas to comprise between about 5% and about 45% of the principle (i.e., active) processing gases. The principle processing gases are generally considered to be chemically reactive gases, such as the carbon monoxide and the chlorine containing gases. If additional oxygen containing gas gases are used they are considered part of the principle gases.

The processing gas may also include an inert gas which, when ionized as part of the plasma including the processing gas, results in sputtering species to increase the etching rate of the features. The presence of an inert gas as part of the plasma may also enhance dissociation of the active processing gases. Examples of inert gases include argon (Ar), helium (He), neon (Ne), xenon (Xe), krypton (Kr), and combinations thereof, of which argon and helium are generally used. The inert gases typically comprise between about 25 vol % and about 30 vol % of the total gas flow for the process.

The total flow of the processing gases, including the inert gases, are between about 100 sccm and about 400 sccm for etching a 150 mm by 150 mm square photolithographic reticles in an etch chamber. Typically, a total processing gas flow between about 200 sccm and about 350 sccm, preferably between about 220 sccm and about 320 sccm, is used in the etching process described herein. However, the total gas flow of the processing gas, including the inert gas flow, may vary based upon a number of processing factors, such as the size of the processing chamber, the size of the substrate being processed, and the specific etching profile desired by the operator.

Generally, the processing chamber pressure is maintained between about 2 milliTorr and about 25 milliTorr. A chamber pressure between about 5 milliTorr and about 20 milliTorr, preferably between about 12 milliTorr and about 18 milliTorr may be maintained during the etching process.

The substrate temperature during processing is about 150° C. or less. A substrate temperature below about 150° C. or less has minimal heat degradation of materials, such as resist materials, deposited on the substrate during the photolithographic reticle fabrication processes with the processing gases described herein. The substrate temperature between about 50° C. and about 150° C., preferably between about 80° C. and about 100° C., may be used to etch photomask features with minimal heat degradation of material disposed on the substrate surface. It is also believed that the substrate temperature helps regulate the formation of passivating polymer deposits by limiting polymerization reactions during the etching process. Additionally, the sidewalls of the processing chamber are maintained at a temperature of less than about 70° C. and the dome is maintained at a temperature of less than about 80° C. to maintain consistent processing conditions and to minimize polymer formation on the surfaces of the processing chamber.

Generally, a source RF power level of about 1000 watts or less is applied to an inductor coil to generate and sustain a plasma of the processing gases during the etching process. A power level between about 300 watts and about 800 watts may be used during the etching process. A power level between about 500 watts and about 700 watts has been observed to provide sufficient plasma of the processing gases sufficient for etching the substrate surface. The recited source RF power levels have been observed to produce sufficient etching radicals and polymerization radicals from the processing gases to etch the exposed metal layer disposed on the substrate while providing a sufficiently low power level compared to prior art metal etch processes for the substrate temperatures to be about 150° C. or less.

Generally, a bias power of less than about 200 watts is applied to the substrate to increase directionality of the etching radicals with respect to the surface of the substrate. A bias power of less than 50 watts, such as between about 5 watts and about 40 watts, may be used in the etching process. A bias between about 5 watts and 20 watts has been observed to provide sufficient directionality of etching radicals during the etching process.

It has been observed that the etching process described herein under the conditions disclosed produces a removal rate ratio, i.e., selectivity, of chrome to resist of about 3:1 or greater. A selectivity of chrome to resist of about 7:1 or greater has been observed in substrate processed by the etching process described herein.

It is believed that generating a plasma of the processing gases at reduced power levels removes exposed portions of the metal layer without excessive etching of the sidewalls of the openings or pattern formed in the resist material and those features being formed in the metal layer during etching to produce the desired critical dimensions. It is also believed that the reduced power levels and reduced substrate temperatures prevent resist degradation to produce features in the metal layer substantially having the critical dimensions of the features defined in the resist material.

While the following description illustrates one embodiment of a process sequence for etching metal layers, such as chromium and chromium oxynitride, as photomasks in photolithographic reticle fabrication, it is contemplated that the etching gases may be used to etch other metal layers formed on substrates in semiconductor and photolithographic reticle manufacturing.

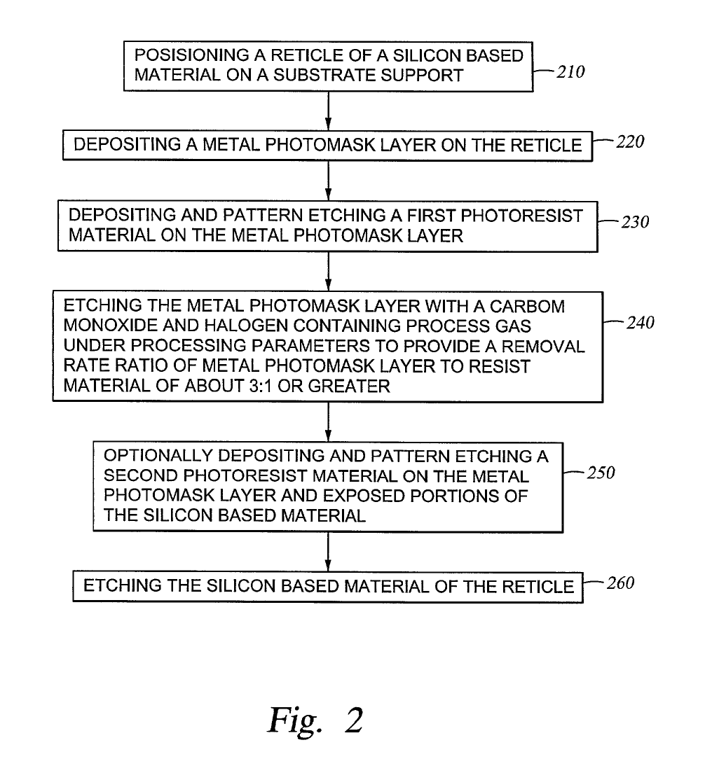

FIG. 2 is a flow chart of one embodiment of one process sequence of an etching process. The flow chart is provided for illustrative purposes and should not be construed as limiting the scope of aspects of the invention. A substrate, typically comprising a silicon-based reticle, such as optical quality quartz, molybdenum silicide, or molybdenum silicon oxynitride (MoSi_{X}N_{Y}O_{Z}) is provided to a processing chamber at step 210, such as the DPS™ processing chamber 10 of FIG. 1. The substrate is then processed by depositing an opaque metal layer as a metal photomask layer, typically comprising chromium, on the substrate at step 220.

The dimensions of openings or patterns to be formed in the metal layer are patterned by depositing and pattern etching a first resist material to expose the metal photomask layer at step 230. The resist materials used in photolithographic reticle fabrication are usually low temperature resist materials, which is defined herein as materials that thermally degrade at temperatures below about 250° C. Resist material may be patterned optically, i.e., photoresist materials, or by another radiative energy patterning device, such as an ion beam emitter. Openings and patterns are then formed by etching the metal photomask layer to expose the underlying substrate at step 240 using the carbon monoxide and halogen containing process gas and processing parameters described herein to provide a removal rate ratio of metal photomask layer to resist material of about 3:1 or greater. Then the remaining resist materials are removed.

Optionally, the substrate may then be further processed to etch the silicon-based materials for use as a phase-shift photolithographic reticle. The silicon-based material of the substrate is prepared for etching by depositing and pattern etching a second resist material 250 on the metal photomask layer and exposed portions of silicon-based material. The substrate is then transferred to a DPS™ processing chamber where a processing gas containing compounds adapted to etch the silicon based material is introduced into the processing chamber and a plasma is generated, thereby etching 260 the exposed silicon based material of the substrate.

One example of etching of the silicon-based reticle of the substrate includes etching with a processing gas comprising fluorocarbon gases as follows. The processing gas comprising fluorocarbon gases having from 1 to 5 atoms of carbon and from 4 to 8 atoms of fluorine including CF₄, C₂F₆, C₄F₆, C₃F₈, C₄F₈, C₅F₈, and combinations thereof, is introduced into a processing chamber, such as the DPS™ described above, at a flow rate between about 25 sccm and about 100 sccm. The chamber is maintained at a pressure between about 2 milliTorr and about 50 milliTorr. An optional inert gas to enhance the etching process may be introduced into the processing chamber at a flow rate between about 30 sccm and about 150 sccm. A source RF power between about 50 watts and about 200 watts is applied to an inductor coil to generate and sustain the plasma during the process. An optional bias power level between about 50 watts and about 200 watts may be applied to the substrate support to enhance control of the etching process. During the etching process, the substrate is maintained at a temperature between about 50° C. and about 150° C. Additionally, the sidewalls 15 of the processing chamber 10 are maintained at a temperature of less than about 70° C. and the dome is maintained at a temperature of less than about 80° C. to maintain consistent processing conditions and to minimize polymer formation on the surfaces of the processing chamber.

Etching of the silicon based material of the substrate by the process described herein is more fully described in co-pending patent application Ser. No. 09/625,313, entitled “A Method and Apparatus for Etching Photomasks,” filed on Jul. 25, 2000, and incorporated herein by reference to the extent not inconsistent with aspects of the invention.

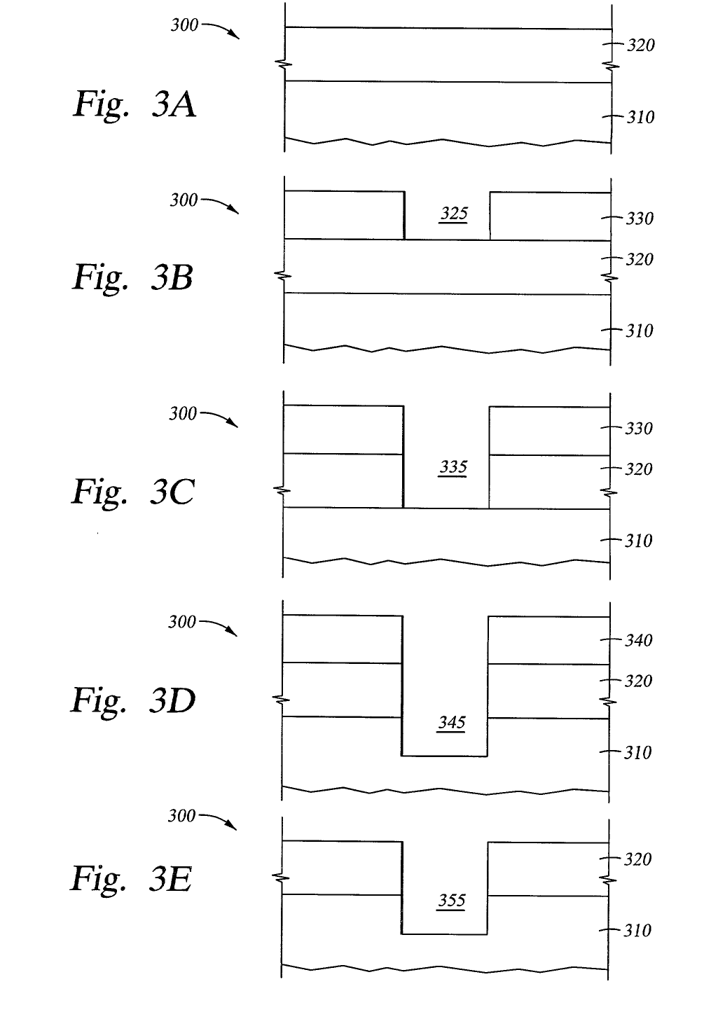

FIGS. 3A-3E illustrate the composition of the photolithographic reticle prior to the etching steps as well as further illustrate the process described above in FIG. 2. A substrate 300, typically made of optical quality quartz material 310, is introduced into a processing chamber. A metal layer 320 made of chromium is deposited on the quartz material 310 as shown in FIG. 3A. The chromium layer may be deposited by conventional methods known in the art, such as by physical vapor deposition (PVD) or chemical vapor deposition (CVD) techniques. The chromium layer 320 is typically deposited to a thickness between about 100 and about 200 nanometers (nm) thick, however, the depth of the layer may change based upon the requirements of the manufacturer and the composition of the materials of the substrate or metal layer.

Referring to FIG. 3B, the substrate 300 is then transferred to another processing chamber where a layer of resist material 330, such as “RISTON,” manufactured by DuPont de Nemours Chemical Company, is deposited upon the chromium layer 320 to a thickness between about 200 and 600 nm thick. The resist material 330 is then pattern etched using conventional laser or electron beam patterning equipment to form a first opening 325 which are used to define the dimensions of the second opening 335 to be formed in the chromium layer 320.

The substrate 300 is then transferred to an etch chamber, such as the DPS™ processing chamber 10 described above, and the chromium layer 320 is etched using metal etching techniques known in the art or by new metal etching techniques that may be developed to form the second opening 335 which expose the underlying quartz material 310 as shown in FIG. 3C.

An exemplary processing regime for etching metal layers on substrates with carbon monoxide and chlorine gas described herein is as follows. The substrate is placed on the support member 16, and a processing gas is introduced into the chamber and a plasma is generated to etch the chromium layer 320.

In one embodiment of the processing gas, the processing gas comprises carbon monoxide, a chlorine containing gas, and an inert gas, typically, carbon monoxide, chlorine gas, and helium. The processing gas is introduced into the processing chamber at a flow rate between about 100 sccm and about 450 sccm. For example, a flow rate of about 265 sccm may be used during the etching process. The carbon monoxide is introduced into the processing chamber at a flow rate between about 40 sccm and about 170 sccm. The chlorine containing gas, for example, chlorine, is introduced into the processing chamber at a flow rate between about 50 sccm and about 150 sccm. The inert gas, for example, helium, is introduced into the processing chamber at a flow rate between about 0 sccm and about 150 sccm. Alternatively, the process gas may include another oxygen containing gas, for example, oxygen, may be introduced into the processing chamber at a flow rate between about 10 sccm and about 50 sccm.

Generally, the processing chamber pressure is maintained between about 2 milliTorr and about 25 milliTorr. A chamber pressure between about 10 milliTorr and about 20 milliTorr may be maintained during the etching process. The actual flow rates of the compounds comprising the processing gas are dependent upon the volume of the processing chamber and the desired amount of etching required.

A source RF power between about 200 watts and about 700 watts is applied to an inductor coil to generate and sustain a plasma of the processing gases during the etching process. A bias power between about 5 watts and about 40 watts is applied to the substrate support. The actual source RF power and bias power levels are dependent upon the needed process controls and type of structures being etched. For example, in advanced photolithographic reticle etch, smaller features need to be etched and a greater degree of control needs to be exercised over the etching process. The greater degree of control is generally achieved by controlling the power levels, typically by reducing the power levels to provide a slower etch.

The substrate temperature is between about 50° C. and about 150° C. during the etching process. Additionally, the sidewalls 15 of the processing chamber 10 are maintained at a temperature of about less than about 70° C. and the dome is maintained at a temperature of less than about 80° C. The above described metal etching process generally produces a selectivity of metal layer to resist of about 2:1 or greater.

Referring to FIGS. 3A-3C, after etching of the chromium layer 320 is completed, the substrate 300 is transferred to a processing chamber, and the remaining resist material 330 is usually removed from the substrate 300, such as by an oxygen plasma process, or other resist removal technique known in the art.

Referring to FIGS. 3D and 3E, the substrate 300 may be further processed to form a phase shift photolithographic reticle by etching the quartz material 310. In etching the quartz material 310, the resist material 330 is removed and a second resist material 340 is applied and patterned to expose the underlying quartz material 310 within the second opening 335. The resist material is deposited to a depth between about 200 nm and 600 nm thick, but may be of any thickness and may also be of the same thickness as the depth of the features to be etched in the quartz material 310 to form the photolithographic reticle. The substrate 300 is then etched to form a third opening 345 in the resist layer 340, the metal layer 320, and the quartz material 310. The second resist material 340 is removed to form a patterned substrate surface 355. The patterned substrate 300 is then transferred to an etch chamber, such as the DPS™ processing chamber 10, for plasma etching the quartz material 310.

The above described processing gas composition and processing regime is believed to provide controllable etching of openings or patterns with desired critical dimensions. The etching of the openings or patterns may be managed by producing and controlling the formation of passivating polymer deposits that condense on the sidewalls and bottom of the openings. It is believed that the passivating polymer deposits are etched and removed from the surface before the underlying material may be etched, thereby resulting in a decrease in the etching rate of the material underlying the passivating polymer deposits and improved selectivity to resist removal over metal layer removal.

Additionally, the plasma etching process is generally anisotropic. The anisotropic process removes material deposited on the bottom of the opening at a higher rate than material on the sidewalls of the opening. This results in passivating polymer deposits on the sidewalls of the openings being removed at a lower rate than passivating polymer deposits on the bottoms of openings. The combination of the anisotropic etch of the plasma etching process and the passivating polymer deposits formed on the sidewalls of openings will increase the etching rate of the bottom of the opening in contrast to the etching rate of the sidewalls of the opening. An etch process that etches the sidewalls of the openings at a slower rate will be less likely to over-etch the sidewalls of the openings during the etching process will allow for improved preservation of the critical dimensions of the openings being etched, and, thus, will reduce etching bias.

In a further embodiment of the invention, the oxygen content of the processing gas may be increased during the etching process by the further addition of another oxygen containing gas. The oxygen containing gas, such as oxygen is added to the processing gas to increase the oxygen content between about 5% and about 45% of the principle gases in the processing gas.

It is believed that chromium layers deposited by physical vapor deposition techniques or chemical vapor deposition techniques CVD processes may incorporate contaminants, such as oxygen and nitrogen, during deposition or during substrate handling. Oxygen and nitrogen in the deposited chromium material form chromium oxynitride, which is mainly concentrated in the upper surface of the deposited material, such as the upper 30% of the chromium layer. The chromium oxynitride layer performs as an anti-reflective coating for the substrate and thus improves lithographic patterning of the resist material. The chromium oxynitride film is more sensitive to etching with oxygen radicals than chromium films. A reduced amount of oxygen in the processing gas may be used to effectively etch the chromium oxynitride surface compared to etching the bulk of the remaining chromium layer. Once the chromium oxynitride layer is substantially removed, effective etching of the remaining chromium material may be performed with increasing the amount oxygen radicals in the processing gas by increasing the oxygen content of the processing gas. The increase in the oxygen content may be achieved by increasing carbon monoxide addition to the processing gas or introducing an oxidizing gas, such as oxygen gas (O₂), into the processing gas.

The invention is further described by the following examples that are not intended to limit the scope of the claimed invention.

### EXAMPLES

A photolithographic reticle including a substrate made of a silicon based material, preferably optical quality quartz with a chromium photomask layer approximately 100 nanometers (nm) thick disposed thereon is introduced into a processing chamber for resist deposition. A resist, such as “RISTON,” manufactured by duPont de Nemours Chemical Company, is deposited upon the chromium photomask and then patterned using conventional laser or electron beam patterning equipment. The resist deposited on the etched chromium photomask is between about 200 nm and about 600 nm thick, for example, between about 300 nm and about 570 nm thick, but may be of any thickness desired.

The reticle is placed in an etch chamber such as the DPS™ metal etch chamber described above. The patterned substrate described above is placed on the cathode pedestal of the etch chamber, and the chamber was maintained at a pressure of about 12 milliTorr and about 18 milliTorr, such as about 15 milliTorr. A plasma was generated by applying a source RF voltage to the inductor coil at a power level of about 500 Watts. A bias power of 5 Watts was applied to the cathode pedestal. The substrate surface is maintained at a temperature between about 70° C. and about 80° C. The chamber walls and dome were cooled to about 70° C. to maintain a steady etch processing condition. The etching of the opening occurred under the following gas flows:

| | |
|---|---|
| Carbon monoxide (CO), at | 70 sccm |
| Chlorine gas (Cl₂), at | 140 sccm |
| Helium (He), at | 50 sccm. |

The total flow rate was about 260 sccm for the above listed processing gases. The etching process was performed for a sufficient time to form the openings in the metal layer. An etch selectivity of chrome to resist material of about 7:1 or greater was observed.

While foregoing is directed to the exemplary aspects of the invention, other and further aspects of the invention may be devised without departing from the basic scope thereof, and the scope thereof is determined by the claims that follow.

What is claimed is:

1. A method for processing a photolithographic reticle, comprising:
positioning the reticle on a support member in a processing chamber, wherein the reticle comprises a metal photomask layer formed on a silicon based substrate and a patterned resist material deposited on the metal photomask layer;
introducing a processing gas comprising carbon monoxide and a halogen-containing gas into the processing chamber, wherein the carbon monoxide and the chlorine containing gas have a molar ratio between about 1:9 and about 9:1; and
delivering power to the processing chamber to generate a plasma and remove exposed portions of the metal photomask layer.

2. The method of claim 1, wherein the metal photomask layer comprises chromium, chromium oxynitride, or combinations thereof.

3. The method of claim 1, wherein the silicon based substrate comprises an optically transparent silicon based material selected from the group of quartz, molybdenum silicide, molybdenum silicon oxynitride, and combinations thereof.

4. The method of claim 1, wherein the processing gas further comprises an oxygen containing gas selected from the group of oxygen (O₂), carbon dioxide (CO₂), and combinations thereof.

5. The method of claim 1, wherein the processing gas further comprises an inert gas selected from the group of helium, argon, xenon, neon, krypton, and combinations thereof.

6. The method of claim 1, wherein the halogen-containing gas comprises a chlorine containing gas is selected from the group of chlorine (Cl₂), silicon tetrachloride (SiCl₄), boron trichloride (BCl₃), and combinations thereof.

7. The method of claim 1, wherein the carbon monoxide and the chlorine containing gas have a molar ratio of about 1:1.

8. The method of claim 1, wherein the metal photomask layer and the resist material are removed at a removal rate ratio of metal photomask layer to resist material of about 3:1 or greater.

9. The method of claim 1, wherein processing the reticle comprises introducing the processing gas into a processing chamber, maintaining the processing chamber at a pressure between about 2 milliTorr and about 25 milliTorr, maintaining the reticle at a temperature between about 50° C. and about 150° C., and generating a plasma by supplying a source RF power between about 250 Watts and about 700 Watts to a coil to the processing chamber.

10. The method of claim 9, further comprising applying a bias power to the support member of about 50 Watts or less.

11. The method of claim 1, further comprising increasing the oxygen content of the processing gas during etching of the metal layer.

12. The method of claim 11, wherein oxygen is added to the processing gas and comprises between about 5% and about 45% of the processing gas.

13. A method for processing a photolithographic reticle, comprising:
positioning the reticle on a support member in a processing chamber, wherein the reticle comprises a chromium based photomask layer formed on an optically transparent silicon based material and a patterned resist material deposited on the chromium based photomask layer;
introducing a processing gas comprising carbon monoxide and chlorine gas, wherein the molar ratio between carbon monoxide and chlorine gas is about 1:1;
introducing an inert gas;
maintaining a chamber pressure between about 2 milliTorr and about 25 milliTorr;
delivering power to the processing chamber of about 700 watts or less to a coil disposed in the processing chamber to generate a plasma; and
etching exposed portions of the chromium based photomask layer and selectively removing the chromium based photomask layer at a removal rate ratio of chromium based photomask layer to resist material of about 3:1 or greater.

14. The method of claim 13, wherein the chromium based photomask layer comprises chromium, chromium oxynitride, or combinations thereof, and the optically transparent silicon based material comprises quartz, molybdenum silicide, molybdenum silicon oxynitride, or combinations thereof.

15. The method of claim 13, wherein the inert gas is selected from the group of helium, argon, xenon, neon, krypton, and combinations thereof.

16. The method of claim 13, wherein etching the reticle comprises introducing carbon monoxide (CO), chlorine (Cl₂), and helium, into a processing chamber, maintaining the processing chamber at a pressure between about 5 milliTorr and about 20 milliTorr, maintaining the reticle at a temperature between about 50° C. and about 150° C., and generating a plasma by supplying a source RF power between about 250 Watts and about 700 Watts to the processing chamber.

17. The method of claim 16, further comprising applying a bias power to the support member of about 50 Watts or less.

18. The method of claim 13, further comprising increasing the oxygen content of the processing gas during etching of the chromium based photomask layer by introducing an oxygen containing gas to comprise between about 5% and about 45% of the processing gas.

19. The method of claim 15, wherein the resist material and chromium based photomask layer are removed at a removal rate ratio of chromium based photomask layer to resist of about 7:1 or greater.

20. A method for processing a photolithographic reticle, comprising:
positioning the reticle on a support member in a processing chamber having a coil, wherein the reticle comprises a chromium based photomask layer formed on an optically transparent silicon based material and a patterned resist material deposited on the chromium based photomask layer;
introducing a processing gas comprising carbon monoxide, chlorine gas, and an oxygen-containing gas into the processing chamber, wherein the molar ratio between carbon monoxide and chlorine gas is about 1:1, and the oxygen-containing gas comprises between about 5% and about 45% of the processing gas;
introducing helium into the processing chamber;
generating a plasma in the processing chamber; and
etching exposed portions of the chromium based photomask layer and selectively removing the chromium based photomask layer at a removal rate ratio of chromium based photomask layer to resist material of about 3:1 or greater.

21. The method of claim 20, wherein the chromium based photomask layer comprises chromium, chromium oxynitride, or combinations thereof.

22. The method of claim 20, wherein the oxygen containing gas is selected from the group of oxygen (O₂), carbon monoxide (CO), carbon dioxide (CO₂), and combinations thereof.

23. The method of claim 20, wherein processing the reticle comprises introducing the processing gas into the processing chamber, maintaining the processing chamber at a pressure between about 2 milliTorr and about 25 milliTorr, maintaining the reticle at a temperature between about 50° C. and about 150° C., generating a plasma by supplying a source RF power between about 250 Watts and about 700 Watts to a coil to the processing chamber, and supplying a bias power to the support member of about 50 Watts or less.

24. The method of claim 20, wherein the resist material and chromium based photomask layer are removed at a removal rate ratio of chromium based photomask layer to resist of about 7:1 or greater
